(19) United States
(12) Patent Application Publication
(10) Pub. No.: US 2026/0107549 A1
(43) Pub. Date: Apr. 16, 2026

(54) TRANSISTORS HAVING VARYING THICKNESSES OF GATE DIELECTRIC LAYERS

(71) Applicant: GlobalFoundries Singapore Pte. Ltd., Singapore (SG)

(72) Inventors: YONG WAH SEE, Singapore (SG); GUOWEI ZHANG, Singapore (SG)

(21) Appl. No.: 18/912,523

(22) Filed: Oct. 10, 2024

(51) Int. Cl. H01L 29/423; H01L 21/02; H01L 21/762

(52) U.S. Cl. CPC H10D 64/516; H10P 14/69215; H10W 10/0124; H10W 10/13

(57) ABSTRACT

The embodiments herein relate to transistors having varying thicknesses of gate dielectric layers. The transistor includes a gate dielectric layer between a gate electrode and a substrate. The gate dielectric layer includes a first dielectric portion on the substrate, a second dielectric portion at least partially in the substrate, and a third dielectric portion partially in the substrate between the first and second dielectric portions. The second dielectric portion is thicker than the first dielectric portion. The third dielectric portion is thicker than the first dielectric portion and thinner than the second dielectric portion.

### TECHNICAL FIELD

The present disclosure relates generally to semiconductor devices, and more particularly to transistors having varying thicknesses of gate dielectric layers and methods of forming the same.

### BACKGROUND

Semiconductor devices play many roles in society, including a crucial role in the conditioning and distribution of power and energy in the world. Transistors, such as laterally-diffused field-effect transistors (LDMOS) and extended-drain field-effect transistors (EDMOS), are capable of handling a wide range of power levels. These transistors can be found in systems delivering as little as a few tens of milliwatts for a headphone amplifier, up to around a gigawatt in a high-voltage direct current transmission line.

Technology advancement in the semiconductor industry comes with a continuing demand for greater integration of semiconductor devices onto a semiconductor chip to provide a multitude of functions. However, integrating transistors designed to handle varying levels of voltages may be challenging to achieve a high figure of merit for the semiconductor chip. Therefore, to meet the growing needs of the semiconductor industry, transistors that support improved integration of varying levels of voltages and methods of forming the same are provided.

### SUMMARY

To achieve the foregoing and other aspects of the present disclosure, transistors having varying thicknesses of gate dielectric layers and methods of forming the same are presented.

According to an aspect of the present disclosure, a transistor is provided. The transistor includes a gate dielectric layer between a gate electrode and a substrate. The gate dielectric layer includes a first dielectric portion on the substrate, a second dielectric portion at least partially in the substrate, and a third dielectric portion partially in the substrate between the first and second dielectric portions. The second dielectric portion is thicker than the first dielectric portion. The third dielectric portion is thicker than the first dielectric portion and thinner than the second dielectric portion.

According to an aspect of the present disclosure, a transistor is provided. The transistor includes a gate dielectric layer between a gate electrode and a substrate. The gate dielectric layer includes a first dielectric, a second dielectric portion, and a third dielectric portion between the first dielectric portion and the second dielectric portion. The first dielectric portion is on an upper substrate surface of the substrate. The second dielectric portion has an upper portion over the upper substrate surface and a lower portion below the upper substrate surface. The third dielectric portion is between the first dielectric portion and the second dielectric portion, and has an upper portion over the upper substrate surface and a lower portion below the upper substrate surface.

According to another aspect of the present disclosure, a method of forming a transistor is provided. The method includes forming an isolation structure in a substrate and forming a gate dielectric layer adjacent to the isolation structure. The gate dielectric layer includes a first dielectric portion on the substrate, a second dielectric portion at least partially in the substrate, and a third dielectric portion partially in the substrate between the first dielectric portion and the second dielectric portion. The second dielectric portion is thicker than the first dielectric portion. The third dielectric portion is thicker than the first dielectric portion and thinner than the second dielectric portion. A gate electrode is formed over the gate dielectric layer.

### BRIEF DESCRIPTION OF THE DRAWINGS

The embodiments of the present disclosure will be better understood from a reading of the following detailed description, taken in conjunction with the accompanying drawings.

FIG. 1 is a cross-sectional view of a semiconductor device, according to an embodiment of the disclosure.

FIGS. 2A to 2G are cross-sectional views that illustrate a method of forming the semiconductor device in FIG. 1, according to an embodiment of the disclosure.

For simplicity and clarity of illustration, the drawings illustrate the general manner of construction, and certain descriptions and details of features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The present disclosure relates to semiconductor devices, and more particularly to transistors having varying thicknesses of gate dielectric layers and methods of forming the same. High-performing transistors are typically indicated by a high figure of merit, which evaluates transistors by taking into consideration conduction losses and switching losses. However, integrating transistors designed to handle varying levels of voltages may be challenging. For example, a transistor intended to support a lower voltage level may have a thinner gate dielectric layer, while a transistor intended to support a higher voltage level may require a thicker gate dielectric layer to achieve a better figure of merit.

Various embodiments of the present disclosure are now described in detail with accompanying drawings. It is noted that like and corresponding elements are referred to by the use of the same reference numerals. The embodiments disclosed herein are exemplary, and not intended to be exhaustive or limiting to the disclosure.

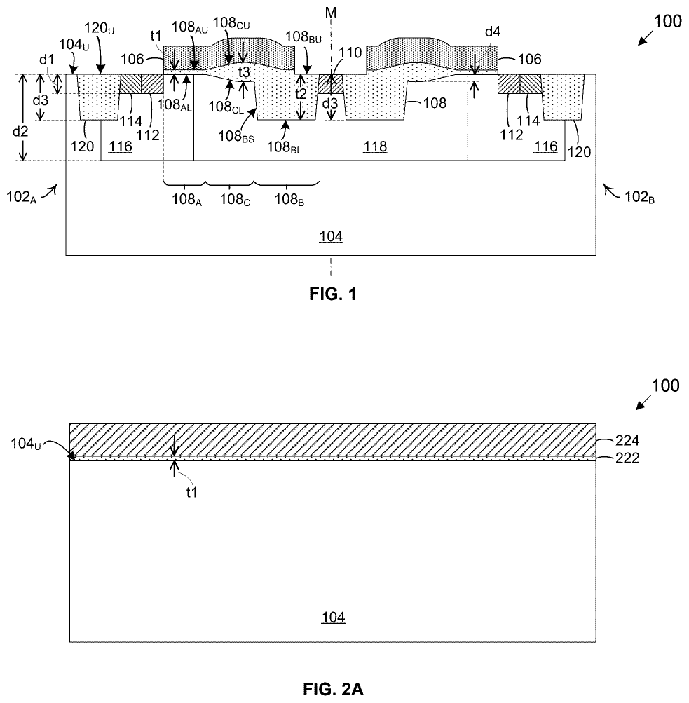

FIG. 1 is a cross-sectional view of a semiconductor device 100, according to an embodiment of the disclosure. The semiconductor device 100 may be part of a semiconductor chip (not shown). The semiconductor device 100 may include a transistor 102_{A} and a transistor 102_{B}. The transistor 102_{A} and the transistor 102_{B} may have mirror symmetry about a plane M through the center of the semiconductor device 100. However, the semiconductor device 100 need not include both transistors 102_{A} and 102_{B}. For example, the semiconductor device 100 may include the transistor 102_{A} or the transistor 102_{B}. In an embodiment of the disclosure, each transistor 102_{A}, 102_{B} may be an asymmetrical field-effect transistor (FET), such as a laterally-diffused field-effect (LDMOS) transistor. For brevity, the semiconductor device 100 will be described below mainly with reference to the transistor 102_{A}, noting that the transistor 102_{B} may have similar elements to the transistor 102_{A}.

The transistor 102_{A} may include a substrate 104 with an upper substrate surface 104_{U}. The upper substrate surface 104_{U} may be an uppermost surface of the substrate 104, and the uppermost surface may be planar. The substrate 104 may include a monocrystalline semiconductor material, for example, silicon, silicon germanium, silicon carbide, or other II-VI or III-V semiconductor compounds. The substrate 104 may be a bulk semiconductor substrate, as illustrated, or a layered semiconductor substrate (not shown), such as a semiconductor-on-insulator (SOI) substrate.

The transistor 102_{A} may further include a plurality of elements, such as a gate electrode 106, a gate dielectric layer 108, and a plurality of doped regions 110, 112, 114, 116, 118. The transistor 102_{A} may include other elements not illustrated in FIG. 1, such as dielectric spacers on sidewalls of the gate dielectric layer 108 and conductive contacts to electrically couple the transistor 102_{A} to other elements of the semiconductor device 100 and/or semiconductor chip.

The gate electrode 106 may be spaced apart from the substrate 104 by the gate dielectric layer 108. As illustrated in FIG. 1, the gate electrode 106 may be over the substrate 104. Alternatively, the gate electrode 106 may be partially or completely within the substrate 104, as long as the gate electrode 106 is spaced apart from the substrate 104 by the gate dielectric layer 108. The gate electrode 106 may include an electrically conductive material, such as polycrystalline silicon, and the gate dielectric layer 108 may include an electrically insulative material, preferably an oxide of the semiconductor material of the substrate 104, such as silicon dioxide.

The plurality of doped regions 110, 112, 114, 116, 118 is in the substrate 104. The doped region 110 may serve as a drain region, the doped region 112 may serve as a source region, and the doped region 114 may serve as a body contact region. The doped regions 112, 114 may be arranged in a doped region 116, which may also be commonly referred to as a body well. The doped region 110 may be arranged in a doped region 118, which may also be commonly referred to as a drift well. As disclosed above, the transistor 102_{B} may be a mirror image of the transistor 102_{A} about the plane M through the center of the semiconductor device 100. In particular, the plane M may be through a center of the doped region 110, and the doped region 110 may be a shared, or common, doped region between the transistor 102_{A} and the transistor 102_{B}.

In an embodiment of the disclosure, the doped regions 110, 112, 116, 118 may include dopants having the same conductivity, such as n-type conductivity. Examples of n-type conductivity dopants may include arsenic, phosphorus, or antimony. The doped region 114 may include dopants having an opposite conductivity to the doped regions 110, 112, 116, 118, such as p-type conductivity. Examples of p-type conductivity dopants may include boron, aluminum, or gallium. Alternatively, the doped regions 110, 112, 116, 118 may include dopants of p-type conductivity and the doped region 114 may include dopants of n-type conductivity.

The plurality of doped regions 110, 112, 114, 116, 118 may extend downward from the upper substrate surface 104_{U}. The doped regions 110, 112, 114 may extend to depth d1 in the substrate 104, and the doped regions 116, 118 may extend to a deeper depth d2 in the substrate 104. Although the doped regions 110, 112, 114 are illustrated to have a similar depth, i.e., depth d1, the depth of each doped region 110, 112, 114 may vary depending on the technology node and design requirements for the semiconductor device 100. Similarly, the doped regions 116, 118 are illustrated to have a similar depth, i.e., depth d2, however, the depths of each doped region 116, 118 may also vary depending on the technology node and design requirements for the semiconductor device 100. It is also understood that the doped regions 110, 112, 114, 116, 118 may not have the same form as illustrated in FIG. 1.

An isolation structure 120 may at least electrically isolate the transistor 102_{A} from adjacent electrically conductive elements, such as another semiconductor device. The isolation structure 120 may also be commonly referred to as a shallow trench isolation (STI) structure. The isolation structure 120 may include the same electrically insulative material as the gate dielectric layer 108, such as silicon dioxide. The isolation structure 120 may include an upper surface 120_{U} and the isolation structure 120 may extend downward from the upper surface 120_{U} to depth d3 in the substrate 104, depth d3 may be deeper than depth d1. In an embodiment of the disclosure, the upper surface 120_{U} of the isolation structure 120 may be substantially coplanar with the upper substrate surface 104_{U}. Even though depth d3 is illustrated to be shallower than depth d2 in FIG. 1, depth d3 may be deeper than depth d2 in other embodiments of the disclosure.

The gate dielectric layer 108 of the semiconductor device 100 may have varying thicknesses. For example, the gate dielectric layer 108 may include a first dielectric portion 108_{A}, a second dielectric portion 108_{B}, and a third dielectric portion 108_{C} laterally between and adjoining the first and second dielectric portions 108_{A}, 108_{B} at opposite ends. In an embodiment of the disclosure, the first dielectric portion 108_{A} may have a thickness t1, which may be the minimum thickness of the first dielectric portion 108_{A}, the second dielectric portion 108_{B} may have a thickness t2, which may be the minimum thickness of the second dielectric portion 108_{B}, and the third dielectric portion 108_{C} may have a thickness t3, which may be the maximum thickness of the third dielectric portion 108_{C}. As illustrated, thickness t1 may be the thinnest, thickness t2 may be the thickest, and thickness t3 may be greater than thickness t1 and lesser than thickness t2.

The first dielectric portion 108_{A} may be on the substrate 104 and in physical contact with the upper substrate surface 104_{U}. The first dielectric portion 108_{A} may be substantially planar with a substantially uniform thickness, i.e., thickness t1. The first dielectric portion 108_{A} may be closest to the doped region 112 and farthest from the doped region 110 compared to the second and third dielectric portions 108_{B}, 108_{C}. In an embodiment of the disclosure, thickness t1 is the minimum thickness of the first dielectric portion 108_{A}.

The second dielectric portion 108_{B} may be at least partially in the substrate 104. For example, the second dielectric portion 108_{B} may have a lower portion below the upper substrate surface 104_{U} and an upper portion over the upper substrate surface 104_{U}. More specifically, the second dielectric portion 108_{B} may be at least predominantly in the substrate 104, such that at least 80% of the cross-sectional area of the second dielectric portion 108_{B} may be under the upper substrate surface 104_{U}. The second dielectric portion 108_{B} may extend to a substantially uniform depth in the substrate 104, measured between the lower surface 108_{BL} and the upper substrate surface 104_{U}. The depth of the second dielectric portion 108_{B} may be similar to that of the isolation structure 120, i.e., depth d3.

The lower surface 108_{BL} of the second dielectric portion 108_{B} may be substantially planar, and the substantially planar lower surface 108_{BL} may adjoin a substantially planar sidewall 108_{BS} at a convex corner in the substrate 104. The second dielectric portion 108_{B} may be closest to the doped region 110 and farthest from the doped region 112 compared to the first and third dielectric portions 108_{A}, 108_{C}. In an embodiment of the disclosure, at least a portion of the upper surface 108_{BU} may be substantially coplanar with the upper substrate surface 104_{U}. In another embodiment of the disclosure, at least a portion of the upper surface 108_{BU} may be substantially coplanar with the upper surface 120_{U} of the isolation structure 120. As such, thickness t2 of the second dielectric portion 108_{B} may be similar to depth d3. In an embodiment of the disclosure, thickness t2 is the minimum thickness of the second dielectric portion 108_{B}.

The third dielectric portion 108_{C} may be partially in the substrate 104. For example, the third dielectric portion 108_{C} may have a lower portion below the upper substrate surface 104_{U} and an upper portion over the upper substrate surface 104_{U}. The lower portion of the third dielectric portion 108_{C} may extend downward to depth d4 below the upper substrate surface 104_{U}. The upper surface 108_{CU} of the third dielectric portion 108_{C} may be above the upper substrate surface 104_{U} while the lower surface 108_{CL} of the third dielectric portion 108_{C} may be below the upper substrate surface 104_{U}. In particular, the lower surface 108_{CL} of the third dielectric portion 108_{C} may be between the lower surface 108_{AL} of the first dielectric portion 108_{A} and the lower surface 108_{BL} of the second dielectric portion 108_{B}, in a vertical direction that is substantially perpendicular to the upper substrate surface 104_{U}.

Additionally, the upper surface 108_{CU} of the third dielectric portion 108_{C} may be above the upper surface 108_{AU} of the first dielectric portion 108_{A} and the upper surface 108_{BU} of the second dielectric portion 108_{B}. The lower and upper surfaces 108_{CL}, 108_{CU} of the third dielectric portion 108_{C} may be convex surfaces that taper towards each other at the end portions of the third dielectric portion 108_{C} to adjoin the first and second dielectric portions 108_{A}, 108_{B}. In particular, at least the end portion of the third dielectric portion 108_{C} adjoining the first dielectric portion 108_{A} may taper and narrow into a bird's beak profile. Accordingly, in this embodiment of the disclosure, thickness t3 of the third dielectric portion 108_{C} may refer to the thickest part, i.e., the maximum thickness, of the third dielectric portion 108_{C}, and the thickness of the third dielectric portion 108_{C} may progressively decrease towards at least the first dielectric portion 108_{A}. As illustrated in FIG. 1, the thickness of the third dielectric portion 108_{C} may progressively decrease towards the first and second dielectric portions 108_{A}, 108_{B}.

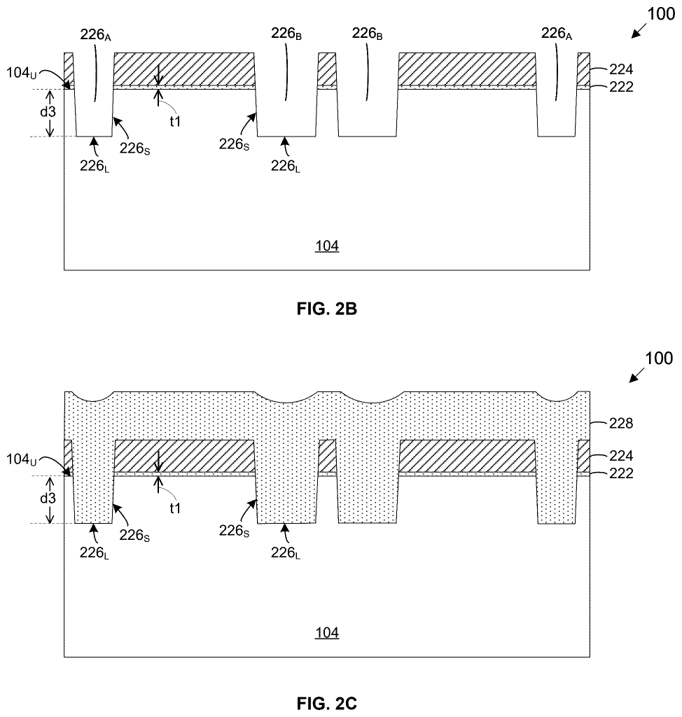

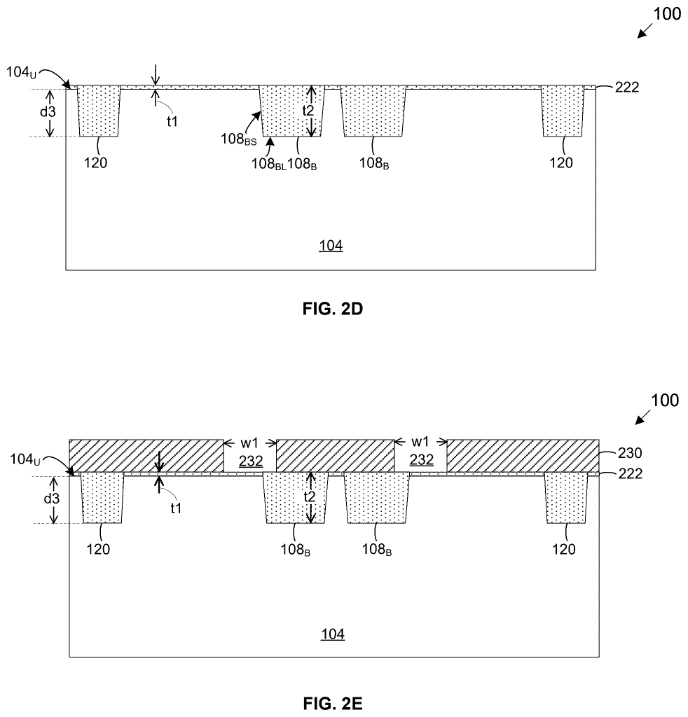

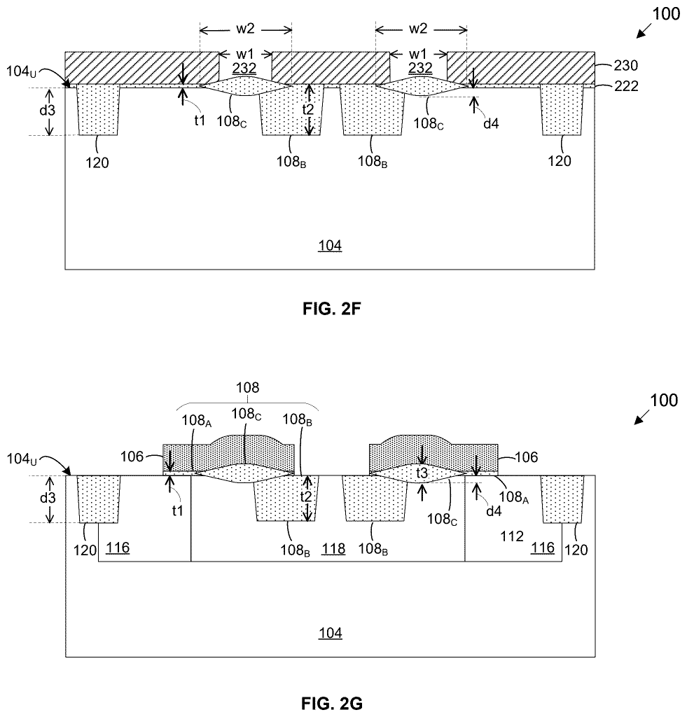

FIGS. 2A to 2G are cross-sectional views that illustrate a method of forming the semiconductor device 100 in FIG. 1, according to an embodiment of the disclosure. Certain structures may be fabricated, for example, using known processes and techniques, and specifically disclosed processes and methods may be used to achieve individual aspects of the present disclosure.

As used herein, “deposition techniques” refer to the process of applying a material over another material (or the substrate). Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD).

Additionally, “patterning techniques” include deposition of material or photoresist, patterning, exposure, development, etching, cleaning, and/or removal of the material or photoresist as required in forming a described pattern, structure, or opening. Exemplary examples of techniques for patterning include, but not limited to, wet etch photolithographic processes, dry etch photolithographic processes, or direct patterning processes. Such techniques may use mask sets and mask layers with dopants having a desired conductivity type.

As illustrated in FIG. 2A, the semiconductor device 100 may include a substrate 104 with an upper substrate surface 104_{U}. The substrate 104 may include a monocrystalline semiconductor material, for example, silicon, silicon germanium, silicon carbide, or other II-VI or III-V semiconductor compounds. An oxide layer 222 may be formed on the substrate 104. The oxide layer 222 may be thermally grown on the substrate 104 using an oxidation technique, such as a blanket thermal oxidation process. The oxidation technique may oxidize the upper substrate surface 104_{U} to form the oxide layer 222, which is an oxide of the semiconductor material of the substrate 104, such as silicon dioxide. The oxide layer 222 may be substantially planar having a substantially uniform thickness t1. The oxide layer 222 may also be commonly referred to as the pad oxide layer.

A mask 224 may be subsequently formed on the oxide layer 222. The term “mask” may refer to a layer of material applied over an underlying layer that allows for selective processing of the underlying layer, such as the oxide layer 222. The mask 224 may be deposited using a deposition technique, including a CVD process. The mask 224 may include an electrically insulative material different from the oxide layer 222, such as silicon nitride. The mask 224 may also serve as an etch stop layer for subsequent processing of the semiconductor device 100.

FIG. 2B is a cross-sectional view of the semiconductor device 100 at a fabrication stage after FIG. 2A, according to an embodiment of the disclosure. Trenches 226_{A}, 226_{B} may be formed in the substrate 104 through the mask 224. The trenches 226_{A}, 226_{B} may be formed using a patterning technique, including lithography and etching processes. The trenches 226_{A} may or may not have similar widths as the trenches 226_{B}, and the trenches 226_{A}, 226_{B} may extend downward to a substantially similar and uniform depth d3 below the upper substrate surface 104_{U}. The trenches 226_{A}, 226_{B} may each have a substantially planar lower surface 226_{L,} and the substantially planar lower surface 226_{L} may adjoin a substantially planar sidewall 226_{S} at a convex corner in the substrate 104.

FIG. 2C is a cross-sectional view of the semiconductor device 100 at a fabrication stage after FIG. 2B, according to an embodiment of the disclosure. The trenches 226_{A}, 226_{B} may be at least completely filled with dielectric material 228. The dielectric material 228 may be deposited using a deposition technique, including a CVD process. The dielectric material 228 may include an electrically insulative material, such as silicon dioxide. It may be preferred that the dielectric material 228 be the same material as the oxide layer 222 as the dielectric material 228 may form a portion of a gate dielectric layer in subsequent processing of the semiconductor device 100.

FIG. 2D is a cross-sectional view of the semiconductor device 100 at a fabrication stage after FIG. 2C, according to an embodiment of the disclosure. An isolation structure 120 and a dielectric portion 108_{B} may be formed in the respective trenches 226_{A}, 226_{B} after removing any excess dielectric material 228 that was deposited outside the trenches 226_{A}, 226_{B}. The isolation structure 120 may be commonly referred to as a shallow trench isolation (STI) structure. Any excess dielectric material 228 may be removed by a material removal technique, including a chemical-mechanical planarization (CMP) process and/or an etching process.

The isolation structure 120 and the dielectric portion 108_{B} may adjoin the oxide layer 222 on the upper substrate surface 104_{U}. The isolation structure 120 and the dielectric portion 108_{B} may have a substantially similar and uniform depth d3 below the upper substrate surface 104_{U}. The isolation structure 120 and the dielectric portion 108_{B} may be at least predominantly in the substrate 104, such that at least 80% of the cross-sectional area of the isolation structure 120 and the dielectric portion 108_{B} may be below the upper substrate surface 104_{U}.

FIG. 2E is a cross-sectional view of the semiconductor device 100 at a fabrication stage after FIG. 2D, according to an embodiment of the disclosure. A mask 230 may be formed over the substrate 104. The mask 230 may include mask openings 232 that expose a part of the oxide layer 222 and an adjacent part of the dielectric portion 108_{B}. The mask 230 may be deposited using a deposition technique, including a CVD process, and subsequently patterned using a patterning technique, including lithography and etching processes, to form the mask openings 232. The mask 230 may include an electrically insulative material different from the oxide layer 222, such as silicon nitride. The mask openings 232 may have width w1, within which a selective oxidation process may subsequently take place. In an embodiment of the disclosure, the exposed part of the dielectric portion 108_{B} may extend about 20% to 50% of width w1. The amount of exposed dielectric portion 108_{B} in the mask openings 232 may be selectively optimized to obtain the associated benefit by providing a desired length of a dielectric portion adjacent to the dielectric portion 108_{B}.

FIG. 2F is a cross-sectional view of the semiconductor device 100 at a fabrication stage after FIG. 2E, according to an embodiment of the disclosure. The semiconductor device 100 may undergo a selective oxidation process to form a dielectric portion 108_{C} adjacent to and adjoining the dielectric portion 108_{B}. The selective oxidation process may be commonly referred to as local oxidation of silicon (LOCOS) process.

The mask 230 may enable selective oxidation of the semiconductor device 100. For example, the mask 230 may mask, or cover, regions of the semiconductor device 100 where no oxidation should occur. In the mask openings 232, the selective oxidation process grows an oxide of the semiconductor substrate material, specifically silicon dioxide, on the substrate 104. The oxide may form the dielectric portion 108_{C} having a thickness t3. During the selective oxidation process, the grown oxide in the mask openings 232 may laterally diffuse along the oxide layer 222 under the mask 230 to form tapered and narrow end portions of the dielectric portion 108_{C} that adjoin the oxide layer 222 and the dielectric portion 108_{B}. The tapered and narrow end portions of the dielectric portion 108_{C} may adopt a bird beak's profile. Due to the material similarity of the dielectric portions 108_{B}, 108_{C} and the oxide layer 222, e.g., silicon dioxide, the interfaces where the dielectric portions 108_{B}, 108_{C} and the oxide layer 222 meet may not be distinct as illustrated in FIG. 2F.

The dielectric portion 108_{C} may be grown partially into the substrate 104. For example, the dielectric portion 108_{C} may have a lower portion in the substrate 104 and an upper portion over the upper substrate surface 104_{U}. The lower portion of the dielectric portion 108_{C} may extend downward to depth d4 below the upper substrate surface 104_{U}. The upper surface of the dielectric portion 108_{C} may be above the upper substrate surface 104_{U} while the lower surface of the dielectric portion 108_{C} may be below the upper substrate surface 104_{U}. The thickness of the dielectric portion 108_{C} grown in the mask openings 232 may be selectively optimized to obtain the associated benefit by providing a desired thickness of a gate dielectric layer portion.

The upper and lower surfaces of the dielectric portion 108_{C} may be convex, and the upper and lower surfaces may taper towards each other at the end portions of the dielectric portion 108_{C} to adjoin the oxide layer 222 and the dielectric portion 108_{B}. In particular, the end portion of the dielectric portion 108_{C} adjoining the oxide layer 222 may taper and narrow into a bird's beak profile.

FIG. 2G is a cross-sectional view of the semiconductor device 100 at a fabrication stage after FIG. 2F, according to an embodiment of the disclosure. The mask 230 and the oxide layer 222 may be removed using a material removal technique, including an etching process. Portions of the substrate 104 may be exposed thereafter, and a layer of oxide (not shown), such as silicon dioxide, may be thermally grown over the exposed substrate 104 using an oxidation technique similar to the oxidation technique in FIG. 2A. The layer of oxide may be grown to have a thickness similar to that shown in FIG. 2A, i.e., thickness t1, or a different thickness depending on the design requirements for the semiconductor device 100.

A gate electrode 106 may be subsequently formed over the substrate 104 by depositing an electrically conductive material, such as polycrystalline silicon. The gate electrode 106 may be deposited using a deposition technique, including a CVD process, and subsequently patterned using a patterning technique, including lithography and etching processes. The gate electrode may have a non-planar upper surface, at least conforming to the upper surface 108_{CU} of the third dielectric portion 108_{C}.

The patterning of the electrically conductive material to form the gate electrode 106 may concurrently pattern the layer of oxide to form a dielectric portion 108_{A}. The dielectric portion 108_{A} may be coterminous with an edge of the gate electrode 106 at one end and may adjoin the dielectric portion 108_{C} at an opposite end thereof. The dielectric portion 108_{A} may be substantially planar with a substantially uniform thickness t1.

The dielectric portions 108_{A}, 108_{B}, 108_{C} may form a gate dielectric layer 108 separating the gate electrode 106 from the substrate 104. The gate electrode 106 may fully overlap the dielectric portion 108_{A} and the dielectric portion 108_{C}, and partially overlap the dielectric portion 108_{B}. The lower surface of the dielectric portion 108_{C} may be between the lower surfaces of the dielectric portions 108_{A}, 108_{B}, and the upper surface of the dielectric portion 108_{C} may be above the upper surfaces 108_{AU}, 108_{BU} of the dielectric portions 108_{A}, 108_{B} in a vertical direction that is substantially perpendicular to the upper substrate surface 104_{U}.

Processing of the semiconductor device 100 continues with forming doped regions 110, 112, 114, 116, 118 in the substrate 104 (see FIG. 1). The doped regions 110, 112, 114, 116, 118 may be formed using a doping technique, including an ion implantation process. The doped region 110 may serve as a drain region, the doped region 112 may serve as a source region, and the doped region 114 may serve as a body contact region. The doped region 110 may be closest to the dielectric portion 108_{B} and farthest from the dielectric portion 108_{A} compared to the doped region 112. The doped region 112 may be closest to the dielectric portion 108_{A} and farthest from the dielectric portion 108_{B} compared to the doped region 110. The doped regions 110, 112, 114 may extend to depth d1 into the substrate. The doped regions 112, 114 may be arranged in a doped region 116, which may also be referred to as a body well. The doped region 110 may be arranged in a doped region 118, which may also be referred to as a drift well. The doped regions 112, 114 may extend to depth d2 into the substrate.

As presented in the above disclosure, transistors having varying thicknesses of gate dielectric layers and methods of forming the same are disclosed. The gate dielectric layer may include a first dielectric portion with a first thickness, a second dielectric portion with a second thickness, and a third dielectric portion with a third thickness laterally between the first and second dielectric portions. The first thickness may be the thinnest, the second thickness may be the thickest, and the third thickness may be greater than the first thickness and lesser than the second thickness. The first, second, and third dielectric portions of the gate dielectric layer are formed using different fabrication techniques.

The second and third dielectric portions may extend partially into a substrate, and form multiple steps in the substrate. In particular, the second and third dielectric portions may extend into a drift region of the transistor. Additionally, due to the varying thicknesses of the gate dielectric layer, the second and third dielectric portions may form multiple steps in the drift region.

The transistor with varying thicknesses of a gate dielectric layer advantageously provides a better figure-of-merit for the transistor. For example, a thinner portion of the gate dielectric layer, such as the first dielectric portion, may support a lower voltage level, while a thicker portion of the gate dielectric layer, such as the second or third dielectric portion, may support a higher voltage level without compromising on the electrical performance of the transistor.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed by interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,” or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it is understood that various changes may be made in the function and arrangement of features and methods of fabrication described in an exemplary embodiment without departing from the scope of this disclosure as set forth in the appended claims.

What is claimed is:

1. A transistor, comprising:
a gate dielectric layer between a gate electrode and a substrate, wherein the gate dielectric layer includes:
a first dielectric portion on the substrate;
a second dielectric portion at least partially in the substrate, the second dielectric portion is thicker than the first dielectric portion; and
a third dielectric portion partially in the substrate between the first dielectric portion and the second dielectric portion, wherein the third dielectric portion is thicker than the first dielectric portion and thinner than the second dielectric portion.

2. The transistor of claim 1, wherein the third dielectric portion has a progressively decreasing thickness towards the first dielectric portion.

3. The transistor of claim 2, wherein the first dielectric portion includes a first upper surface, the second dielectric portion includes a second upper surface, and the third dielectric portion includes a third upper surface, wherein the third upper surface is above the first upper surface and the second upper surface.

4. The transistor of claim 3, wherein the third upper surface is a convex surface.

5. The transistor of claim 3, wherein the substrate includes an upper substrate surface and a portion of the second upper surface is substantially coplanar with the upper substrate surface.

6. The transistor of claim 4, wherein the first dielectric portion includes a first lower surface, the second dielectric portion includes a second lower surface, and the third dielectric portion includes a third lower surface, wherein the second lower surface is below the first lower surface and the third lower surface.

7. The transistor of claim 6, wherein the first and second lower surfaces are substantially planar surfaces and the third lower surface is a convex surface.

8. The transistor of claim 1, wherein the gate electrode fully overlaps the third dielectric portion and partially overlaps the second dielectric portion.

9. A transistor, comprising:
a gate dielectric layer between a gate electrode and a substrate, wherein the gate dielectric layer includes:
a first dielectric portion on an upper substrate surface of the substrate;
a second dielectric portion having an upper portion over the upper substrate surface and a lower portion below the upper substrate surface; and
a third dielectric portion between the first dielectric portion and the second dielectric portion, wherein the third dielectric portion has an upper portion over the upper substrate surface and a lower portion below the upper substrate surface.

10. The transistor of claim 9, wherein the lower portion of the second dielectric portion has a first depth below the upper substrate surface and the third dielectric portion has a second depth below the upper substrate surface, wherein the second depth is shallower than the first depth.

11. The transistor of claim 10, further comprising an isolation structure in the substrate proximate to the first dielectric portion, wherein the isolation structure has a third depth below the upper substrate surface and the third depth is substantially similar to the first depth.

12. The transistor of claim 11, wherein the isolation structure has an upper surface and the second dielectric portion has an upper surface, wherein at least a portion of the upper surface of the second dielectric portion is substantially coplanar with the upper surface of the isolation structure.

13. The transistor of claim 11, wherein the isolation structure includes an electrically insulative material and the gate dielectric layer includes the same electrically insulative material as the isolation structure.

14. The transistor of claim 13, wherein the electrically insulative material is silicon dioxide.

15. A method of forming a transistor, comprising:
forming an isolation structure in a substrate;
forming a gate dielectric layer adjacent to the isolation structure, wherein the gate dielectric layer includes:
a first dielectric portion on the substrate;
a second dielectric portion at least partially in the substrate, the second dielectric portion is thicker than the first dielectric portion; and
a third dielectric portion partially in the substrate between the first dielectric portion and the second dielectric portion, wherein the third dielectric portion is thicker than the first dielectric portion and thinner than the second dielectric portion; and
forming a gate electrode over the gate dielectric layer.

16. The method of claim 15, wherein forming the isolation structure concurrently forms the second dielectric portion of the gate dielectric layer.

17. The method of claim 15, wherein the first, second, and third dielectric portions are each formed using different techniques.

18. The method of claim 17, wherein the second dielectric portion is formed using a chemical vapor deposition process.

19. The method of claim 18, wherein the third dielectric portion is formed using a local oxidation of silicon (LOCOS) process.

20. The method of claim 19, wherein the first dielectric portion is formed using a thermal oxidation process.
